(19) United States
(12) Patent Application Publication
(10) Pub. No.: US 2016/0043030 A1
(43) Pub. Date: Feb. 11, 2016

(54) SEMICONDUCTOR DEVICE AND METHOD FOR MANUFACTURING THE SAME

(71) Applicant: UNITED MICROELECTRONICS CORPORATION, HSINCHU (TW)

(72) Inventors: CHIA-LIN LU, Taoyuan City (TW); CHUN-LUNG CHEN, Tainan City (TW); KUN-YUAN LIAO, Hsinchu City (TW); FENG-YI CHANG, Tainan City (TW)

(73) Assignee: UNITED MICROELECTRONICS CORPORATION, HSINCHU (TW)

(21) Appl. No.: 14/477,851

(22) Filed: Sep. 4, 2014

(30) Foreign Application Priority Data
Aug. 11, 2014 (CN) 201410392447.8

(51) Int. Cl. H01L 23/528; H01L 21/768; H01L 23/522

(52) U.S. Cl. CPC H01L 23/528; H01L 23/5226; H01L 21/76849; H01L 21/76807; H01L 21/76814

(57) ABSTRACT

A semiconductor device and a method for manufacturing the same are provided. The semiconductor device includes a substrate, a first dielectric layer, and a first metal plug structure, wherein a circuit element is disposed on the substrate. The first dielectric layer is disposed on the circuit element and on the substrate. The first metal plug structure, including a first barrier metal layer and a first metal interconnector, is embedded in the first dielectric layer. The first metal interconnector is in direct contact with the circuit element. The first barrier metal layer is disposed on the first metal interconnector; wherein the first barrier metal layer and the first metal interconnect have different metal materials.

### FIELD OF THE INVENTION

The present invention relates to a semiconductor device and a method for manufacturing the same, and more particularly to a semiconductor device and a method for manufacturing the same, wherein the semiconductor device has a metal plug structure having at least two sequentially stacked metal layers.

### BACKGROUND OF THE INVENTION

In a conventional semiconductor manufacturing process, a plurality of contact metal plugs forming in contact holes and a plurality of metal layers are used for connecting to different circuit elements. FIG. 1 is a schematic diagram illustrating a structure of a semiconductor device having contact metal plugs and manufactured by a conventional semiconductor process. Please refer to FIG. 1. In a conventional semiconductor process, a method for forming a metal contact plug in a contact hole includes steps of: providing a substrate 110, wherein a circuit element 120 is disposed on the substrate 110, and a first dielectric layer 130 is covered on the substrate 110 and on the circuit element 120; forming a first contact hole 132 in the first dielectric layer 130, wherein the first contact hole 132 penetrates through the first dielectric layer 130 to expose a portion of the circuit element 120; forming a first metal contact plug 152 in the first contact hole 132; forming a first metal layer 162 on the first metal contact plug 152 and on a portion of the first dielectric layer 130; forming a second dielectric layer 140 on the first metal layer 162; forming a second contact hole 142 in the second dielectric layer 140, wherein the second contact hole 142 penetrates through the second dielectric layer 140 to expose the first metal layer 162; and forming a second metal contact plug 154 in the second contact hole 142.

It is worth noting that during the manufacturing process, position inaccuracy is easily to cause a problem of only a portion, but not all the first metal contact plugs 152 covered by the first metal layer 162. In other words, the first metal layer 162 and the second dielectric layer 140 are all disposed on the first metal contact plug 152 and are all in direct contact with the first metal contact plug 152. Therefore, during a step of forming the second contact hole 142 by using an etching process, dislocation and over-etching problems will cause the second contact hole to be extending downwards to a side of the first metal layer 162. So the second contact hole 142 is configured to expose not only the first metal layer 162, but also the second dielectric layer 140 disposed upon the first metal contact plug 152. When performing a cleaning process on the second contact hole 142 after the etching process, the first metal contact plug 152 will be easily eroded by a chemical detergent used in cleaning the second contact hole 142. So it will damage the semiconductor device and reduce reliability of the semiconductor device.

In view of the aforementioned reasons, there is a need to provide a new semiconductor device and a method for manufacturing the same to solve the aforementioned loss problems of the first metal contact plug.

### SUMMARY OF THE INVENTION

The present invention provides a semiconductor device and a method for manufacturing the same to improve yield of the semiconductor device after performing a process of forming a structure having a metal contact plug.

In order to achieve the aforementioned advantages or other merits, a semiconductor device is provided in an embodiment of the present invention. The semiconductor device includes a substrate, a first dielectric layer, and a first metal plug structure. A circuit element is disposed on the substrate. The first dielectric layer is disposed on the circuit element and on the substrate. The first metal plug structure is embedded in the first dielectric layer, and includes a first metal interconnector and a first barrier metal layer, wherein the first metal interconnector is in direct contact with the circuit element. The first barrier metal layer is disposed on the first metal interconnector; the first metal interconnector and the first barrier metal layer have different metal materials.

A method for manufacturing a semiconductor device is further provided in another embodiment of the present invention. The method includes steps of: providing a substrate, wherein a circuit element is disposed on the substrate; forming a first dielectric layer on the substrate and on the circuit element; forming a first through hole in the first dielectric layer, wherein the first through hole penetrates through the first dielectric layer to expose a portion of the circuit element; forming a first metal interconnector in the first through hole to fill the first through hole, wherein the first metal interconnector is in direct contact with the circuit element; forming a recess in a side of the first metal interconnector away from the circuit element; and forming a first barrier metal layer in the recess, wherein the first barrier metal layer is in direct contact with the first metal interconnector, and the first metal interconnector and the first barrier metal layer have different metal materials.

In summary, a conventional metal plug structure consisting of a single metal material layer is improved to a metal plug structure having at least two sequentially stacked metal material layers (including at least a metal interconnector and a barrier metal layer disposed on thereof) in the present invention. In addition, the material of the barrier metal layer can be selected in accordance with the composition of the chemical detergent which is used for cleaning the through hole after performing etching process, so the metal interconnector of the metal plug structure can be protected and a loss problem of the metal interconnector causing in the cleaning process can be avoided.

For making the above and other purposes, features and benefits become more readily apparent to those ordinarily skilled in the art, the preferred embodiments and the detailed descriptions with accompanying drawings will be put forward in the following descriptions.

### BRIEF DESCRIPTION OF THE DRAWINGS

The present invention will become more readily apparent to those ordinarily skilled in the art after reviewing the following detailed description and accompanying drawings, in which:

FIG. 1 is a schematic diagram illustrating a semiconductor device which has a metal contact plug and is manufactured by a conventional semiconductor process;

FIGS. 2A-2H schematically illustrate a process flow of a method for manufacturing a semiconductor device according to an embodiment of the present invention;

FIGS. 3A-3C schematically illustrate a process flow of a method for forming a recess of a semiconductor device according to another embodiment of the present invention; and

FIG. 4 schematically illustrates a structure of a semiconductor device according to another embodiment of the present invention.

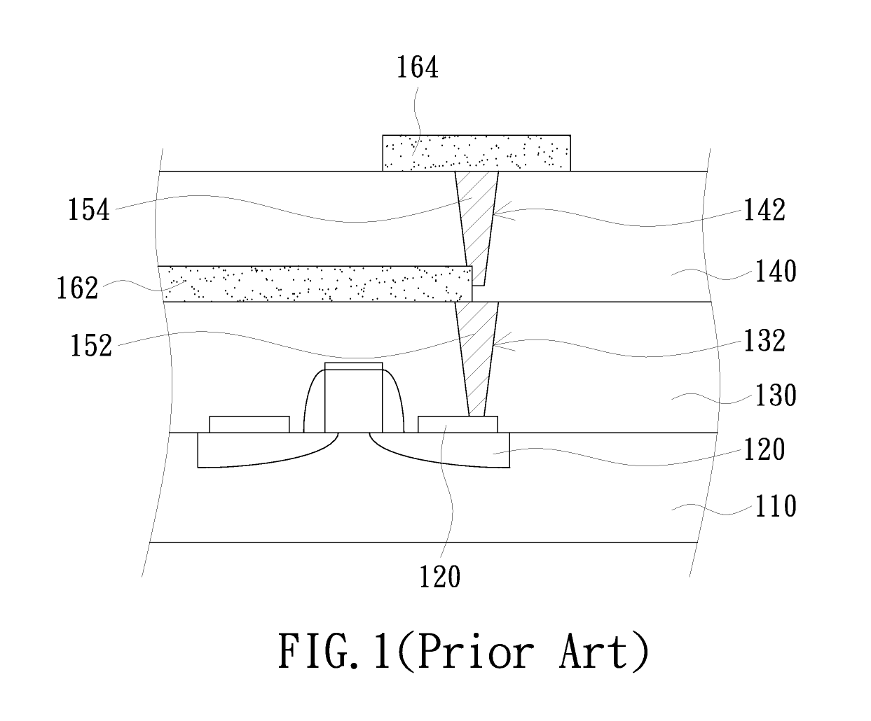

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

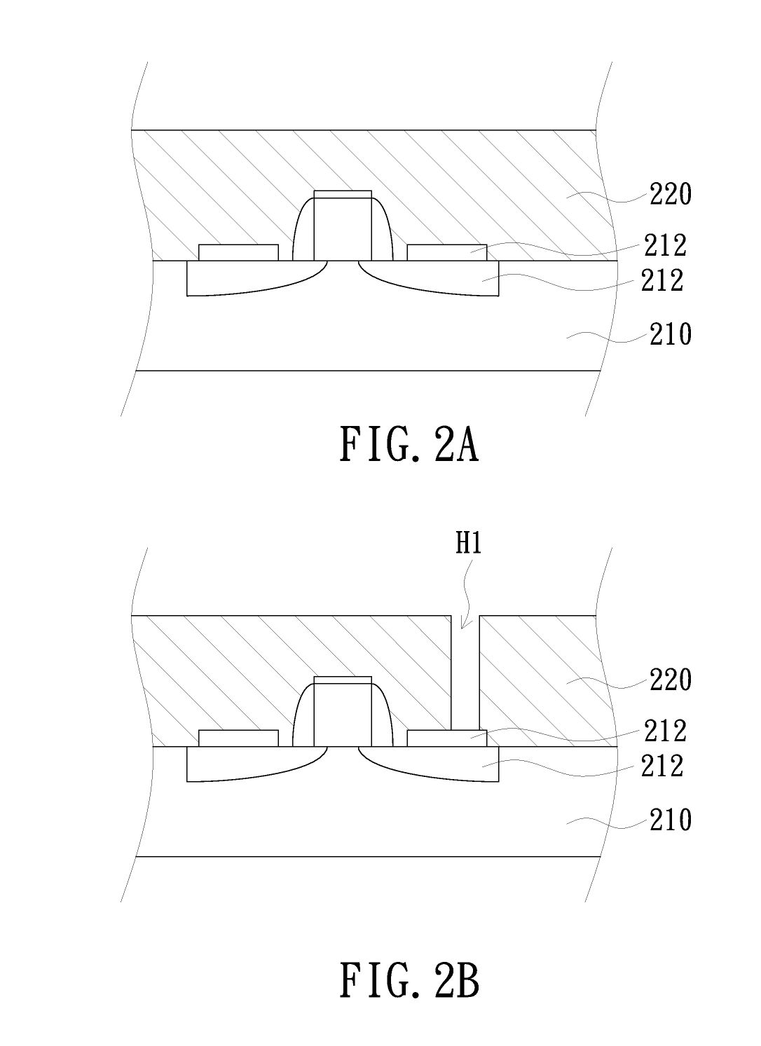

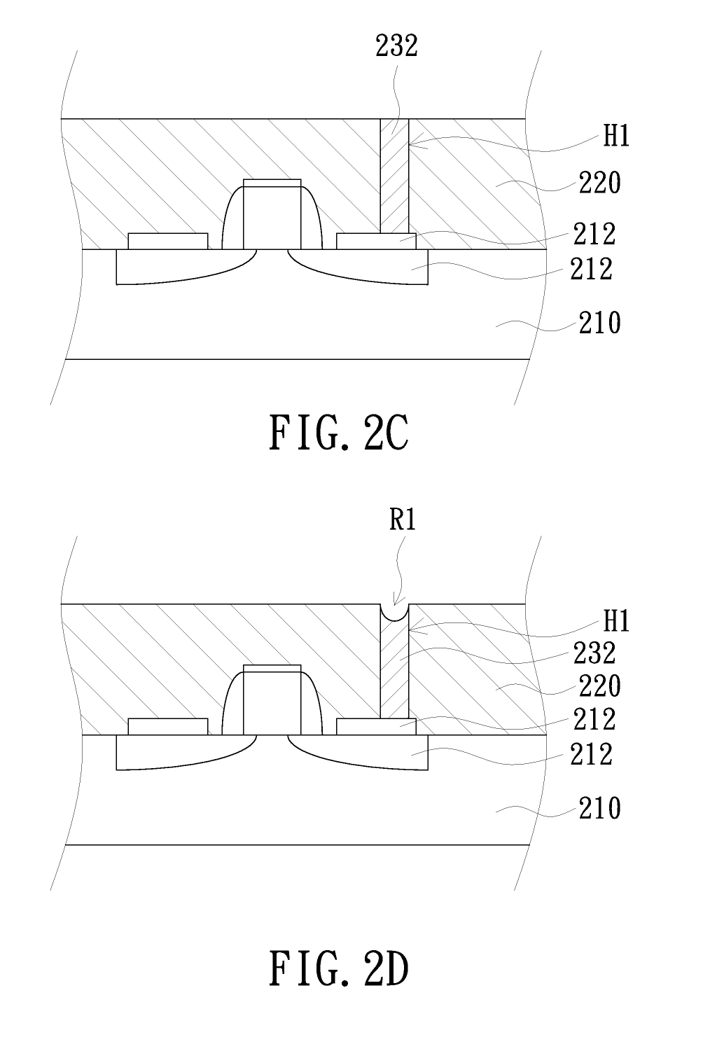

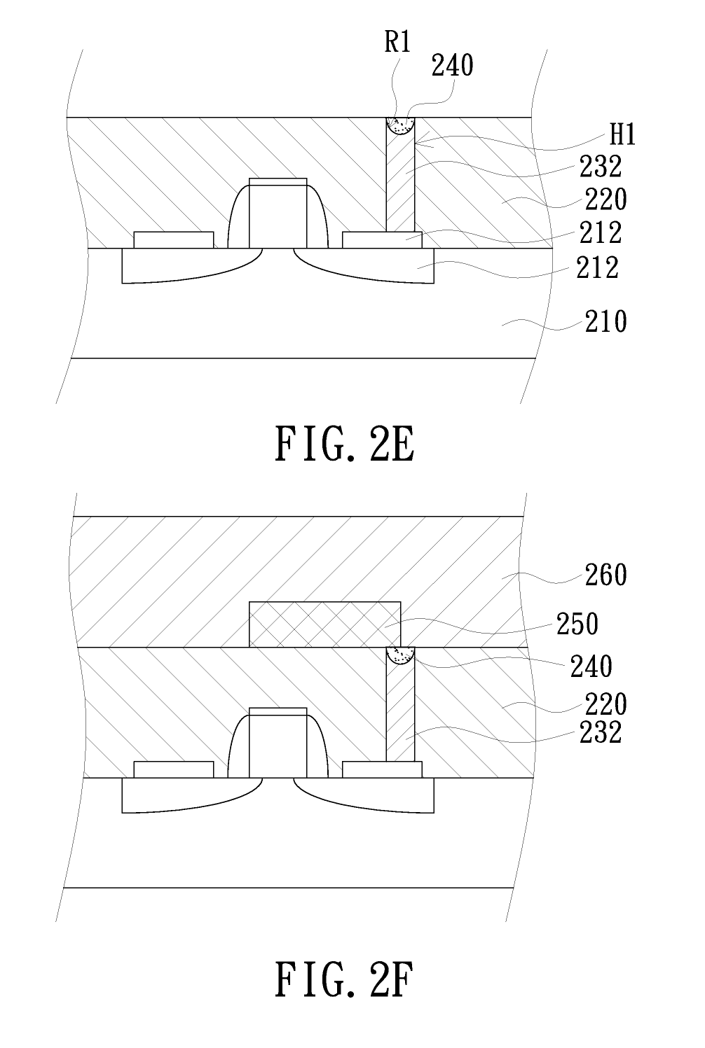

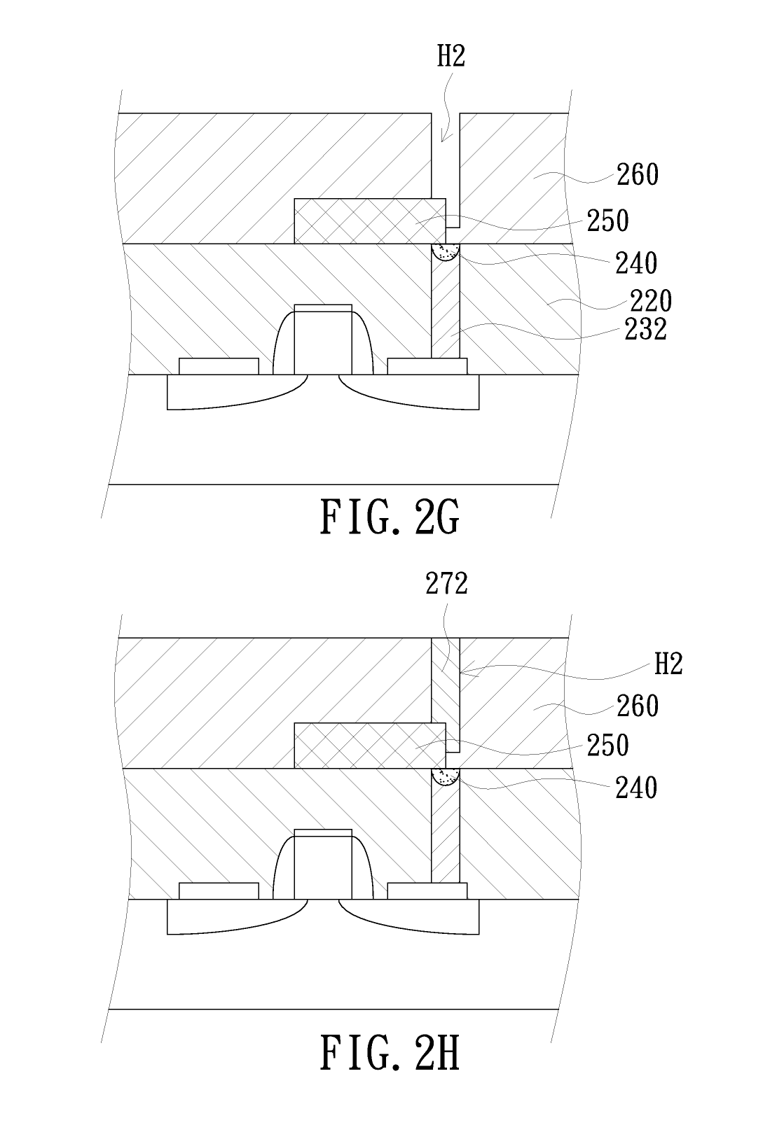

FIGS. 2A-2H schematically illustrate a process flow of a method for manufacturing a semiconductor device according to an embodiment of the present invention. Please refer to FIGS. 2A-2B firstly. The method for manufacturing a semiconductor device provided in the embodiment includes steps of: providing a substrate 210, wherein a circuit element 212 is disposed on the substrate 210; forming a first dielectric layer 220 on the substrate 210 and on the circuit element 212, as shown in FIG. 2A; performing a first etching process to form a first through hole H1 in the first dielectric layer 220, as shown in FIG. 2B. The first through hole H1 penetrates through the first dielectric layer 220 to expose a portion of the circuit element 212. After performing the first etching process to form the first through hole H1, the method for manufacturing the semiconductor device further includes a step of performing a cleaning process on the first through hole H1 to remove residues remaining in the first through hole H1. As illustrated in FIG. 2A, it is understood that the circuit element 212 in this embodiment is exemplified by a field effect transistor; however, all of circuit elements, allowed to be formed in a semiconductor device, can be seen as the circuit element 212, so the present invention is not limited thereto.

Next, please refer to FIG. 2C. After completing the step of forming the first through hole H1, the method for manufacturing the semiconductor device further includes a step of forming a first metal interconnector 232 in the first through hole H1 to fill the first through hole H1, as shown in FIG. 2C. The first metal interconnector 232 is in direct contact with the circuit element 212. In addition, after completing the step of forming the first metal interconnector 232, the method for manufacturing the semiconductor device further includes, for example, a step of performing a chemical mechanical polishing (CMP) process to remove the first metal interconnector 232 that is disposed outside the first through hole H1 and to make a top surface of the first metal interconnector 232 to be flush to a top portion of the first through hole H1.

Next, please refer to FIG. 2D-2E. After completing the step of forming the first metal interconnector 232 in the first through hole H1 and performing the CMP process, the method for manufacturing the semiconductor device further includes a step of removing a portion of the first metal interconnector 232 that is disposed in the top portion of the first through hole H1 to form a recess in a side of the first metal interconnector 232 away from the circuit element 212. The recess is formed by using, for example, a CMP process to remove a portion of the first metal interconnector 232 that is disposed in the top portion of the first through hole H1, so as to form a dishing R1, as shown in FIG. 2D. Next, the method for manufacturing the semiconductor device further includes forming the first barrier metal layer 240 in the dishing R1, as shown in FIG. 2E. Further, for example, the method for manufacturing the semiconductor device further includes a step of removing the first barrier metal layer 240 that is disposed outside the dishing R1 by using a CMP process to make a top surface of the first barrier metal layer 240 to be flush to the top surface of the first dielectric layer 220. The first barrier metal layer 240 is in direct contact with the first metal interconnector 232. In addition, the first metal interconnector 232 and the first barrier metal layer 240 have different metal materials, wherein the metal materials includes common conductive metal materials that is used in the semiconductor processes, and the metal materials can be selected from a group including W, Cu, Al, Ti, Ta, Ag, Au and other metal elements or combinations thereof.

Next, please refer to FIG. 2F. After completing the step of forming the first barrier metal layer 240, the method for manufacturing the semiconductor device further includes a step of forming a first metal layer 250 on the first barrier metal layer 240 and on a portion of the first dielectric layer 220, and then forming a second dielectric layer 260 on the first metal layer 250 and on the first dielectric layer 220, as shown in FIG. 2F. The first metal layer 250 is in direct contact with the first barrier metal layer 240. The second dielectric layer 260 is further disposed on a portion of the first barrier metal layer 240, and the second dielectric layer 260 is in direct contact with the first barrier metal layer 240.

Next, please refer to the FIG. 2G. After completing the step of forming the second dielectric layer 260, the method for manufacturing the semiconductor device further includes a step of performing a second etching process to forming a second through hole H2 in the second dielectric layer 260, as shown in FIG. 2G. The second through hole H2 penetrates the second dielectric layer 260 to expose the first metal layer 250, and the second through hole H2 is further configured to expose the second dielectric layer 260 disposed upon the first barrier metal layer 240. After performing the second etching process to form the second through hole H2, the method for manufacturing the semiconductor device further includes a step of performing a cleaning process on the second through hole H2 to remove residues remaining in the second through hole H2.

Next, please refer to FIG. 2H. After completing the step of forming the second through hole H2 and performing the cleaning process, the method for manufacturing the semiconductor device further includes a step of forming a second metal interconnector 272 in the second through hole H2, as shown in FIG. 2H. And after the step of forming the second metal interconnector 272, a CMP process may be performed to remove the second metal interconnector 272 disposed outside the second through hole H2 and make a top surface of the second metal interconnector 272 be flush to the top surface of the second dielectric layer 260. The second metal interconnector 272 is in direct contact with the first metal layer 250, and a bottom surface of the second metal interconnector 272 is, for example, further configured to be in direct contact with the second dielectric layer 260 which is disposed upon the first barrier metal layer 240. In addition, based on requirements of different manufacturing processes, the method for manufacturing the semiconductor device provided in the embodiment may further include a step of forming an another recess (not shown in figure) in the top surface of the second metal interconnector 272 which is flush to the top surface of the second dielectric layer 260, and then forming a second barrier metal layer (not shown in figure) in the another recess.

In the present invention, the first barrier metal layer 240 formed on the first metal interconnector 232 can be used for preventing the first metal interconnector 232 disposed under the second through hole H2 from being eroded by the chemical detergent which is used for cleaning the second through hole H2 in the cleaning process after the etching process. So the chemical detergent used for cleaning the through holes in the cleaning process is a basis reference for selecting a suitable material to be the first barrier metal layer. In other words, the metal material constituting the first barrier metal layer must have an ability of effectively resisting erosion which results from the chemical detergent used in the cleaning process, so as to make the first barrier metal layer can effectively prevent the first metal interconnector which is disposed under the first barrier metal layer from being eroded by the chemical detergent. So the first barrier metal layer has a metal material different from that of the first metal interconnector. And the second barrier metal layer may also have a metal material different from that of the second metal interconnector.

In a preferred embodiment, the first metal interconnector 232 has a metal material of tungsten (W), for instance. And if a composition of the chemical detergent used in the cleaning process includes ammonium fluoride, heterocyclic compounds, and 2-ethanol, then the first barrier metal layer 240 may have a preferable metal material, such as copper (Cu) or aluminum (Al). Using Cu or Al as the first barrier metal layer 240 can effectively prevent tungsten material of the first metal interconnector 232 from being eroded by the chemical detergent including ammonium fluoride, heterocyclic compounds, and 2-ethanol.

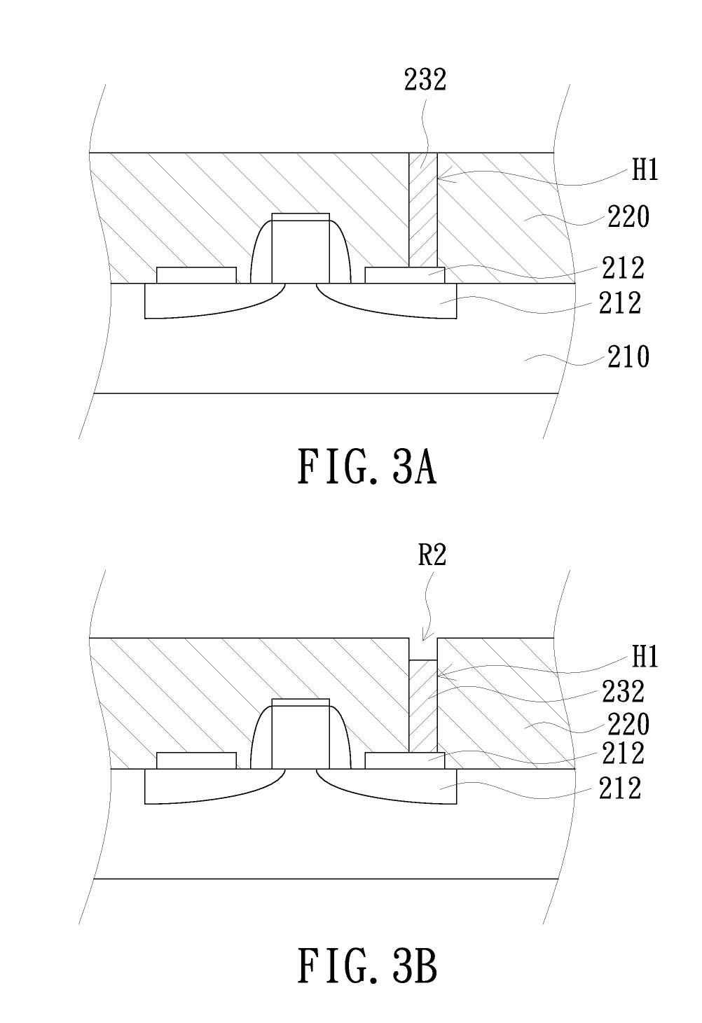

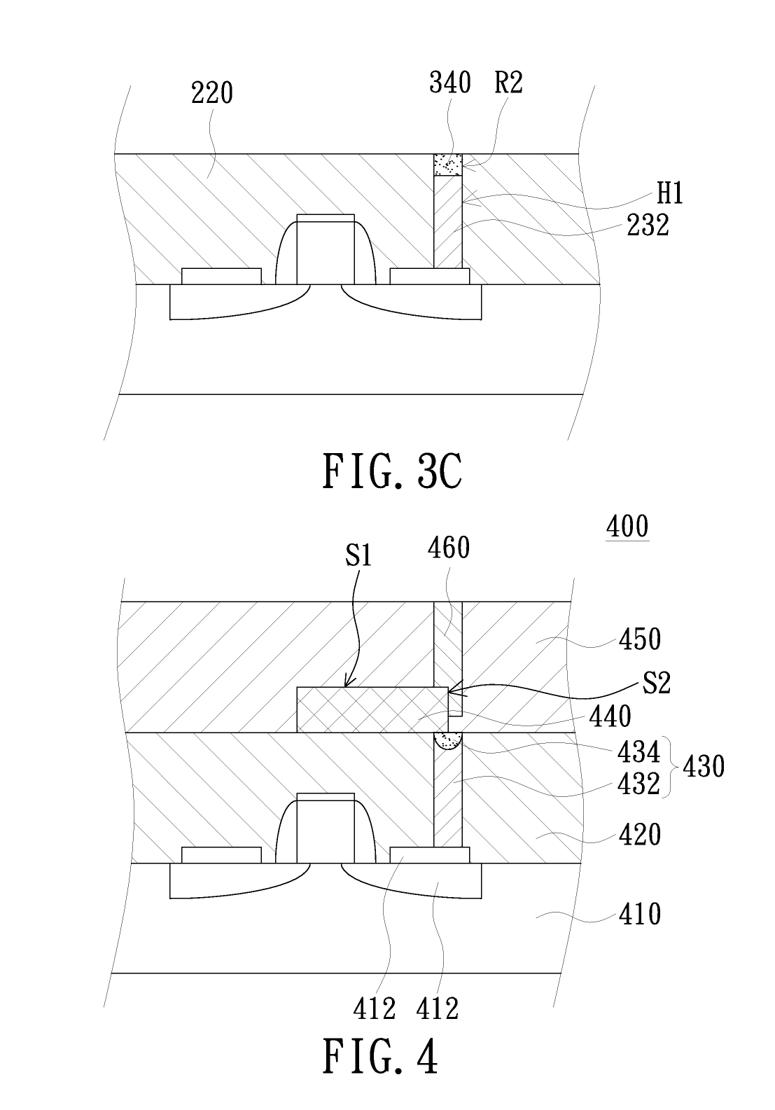

Furthermore, another method for forming another type of a recess is also provided in the present invention. Please refer to FIGS. 3A-3C. The method for forming another type of the recess includes a step of: providing a structure of FIG. 2C, firstly. I.e., the circuit element 212, the first dielectric layer 220, and the first metal interconnector 232 disposed in the first through hole H1, have been disposed on the substrate 210, as shown in FIG. 3A. Next, the method for forming another type of the recess further includes a step of performing an etching back process on the first metal interconnector 232 to remove a portion of the first metal interconnector 232 disposed in a top portion of the first through hole H1 to form a recess R2 in a side of the first metal interconnector 232 away from the circuit element 212, as shown in FIG. 3B. After forming the recess R2, a first barrier metal layer 340 is formed in the recess R2, as shown in FIG. 3C. Other steps performed after the step of forming the first barrier metal layer 340, such as the steps of forming the first metal layer on the first barrier metal layer, forming the second dielectric layer, forming the second through hole, and forming the second metal interconnector, are the same as the process steps shown in FIG. 2F-2H. So the same process steps are not redundantly described herein.

However, it is worth mentioning that although there just two methods for forming a recess are provided in the above mentioned embodiments, such as using the CMP process or using the etching back process, other methods used for forming a recess in semiconductor manufacturing processes could also be applied in the present invention to form a recess; and the present invention is not limited thereto.

FIG. 4 schematically illustrates a structure of a semiconductor device according to another embodiment of the present invention. Please refer to FIG. 4. The semiconductor device of the present invention could be fabricated in accordance with the steps shown in FIGS. 2A-2H or shown in FIGS. 3A-3C. As illustrated in FIG. 4, it is understood that the semiconductor device fabricated in accordance with the steps shown in FIGS. 2A-2H is exemplified in this illustrated embodiment. The semiconductor device 400 includes a substrate 410, a circuit element 412, a first dielectric layer 420, a first metal plug structure 430, a first metal layer 440, a second dielectric layer 450, and a second metal plug structure 460.

Please refer to FIG. 4. The circuit element 412 is disposed on the substrate 410. The first dielectric layer 420 is disposed on the substrate 410 and on the circuit element 412. The first metal plug structure 430 is embedded in the first dielectric layer 420, wherein the first metal plug structure 430 includes a first metal interconnector 432 and a first barrier metal layer 434. The first metal interconnector 432 is in direct contact with the circuit element 412. The first barrier metal layer 434 is disposed on the first metal interconnector 432 and in direct contact with the first metal interconnector 432. The first metal interconnector 432 and the first barrier metal layer 434 have different metal materials. In a preferred embodiment, the first metal interconnector 432 has a metal material of tungsten (W), for instance, and the first barrier metal layer 434 has a material selected from a group including Cu, Al, Ti, Ta, Ag, Au and other metal elements or combinations thereof. The first barrier metal layer 434 has a dish shape. But in other embodiments, the first barrier metal layer 434 may have a cylindrical shape, as the structure of the first barrier metal layer 340 shown in FIG. 3C.

Please refer to FIG. 4. The first metal layer 440 is disposed on the first barrier metal layer 434 and on a portion of the first dielectric layer 420. The second dielectric layer 450 is disposed on the first metal layer 440 and on the first dielectric layer 420, and is further disposed on a portion of the first barrier metal layer 434. The second dielectric layer 450 is in direct contact with the first metal layer 440, the first barrier metal layer 434, and the first dielectric layer 420. In addition, the second metal plug structure 460 is embedded in the second dielectric layer 450 and in direct contact with the first metal layer 440. And the second metal plug structure 460 is further configured to be in direct contact with a first surface S1 of the first metal layer 440 away from the first barrier metal layer 434, and in direct contact with a portion of a second surface S2 of the first metal layer 440; wherein the second surface S2 connects to the first surface S1, and is adjacent to the first barrier metal layer 434. It is worth mentioning that the second metal plug structure 460 includes at least a second metal interconnector. But in other embodiments, the second metal plug structure 460 includes, for example, a second metal interconnector and a second barrier metal layer disposed on the second metal interconnector (not shown in figures).

In summary, a conventional metal plug structure consisting of a single metal material layer is improved to a metal plug structure having at least two sequentially stacked metal material layers (including at least a metal interconnector and a barrier metal layer disposed on thereof) in the present invention. In addition, the material of the barrier metal layer can be selected in accordance with the composition of the chemical detergent which is used for cleaning the through hole after performing an etching process, so the metal interconnector of the metal plug structure can be protected and a loss problem of the metal interconnector causing in the cleaning process can be avoided.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A semiconductor device, comprising:
a substrate, wherein a circuit element is disposed on the substrate;
a first dielectric layer, disposed on the circuit element and the substrate; and
a first metal plug structure, embedded in the first dielectric layer, and including a first metal interconnector and a first barrier metal layer, wherein the first metal interconnector is in direct contact with the circuit element, the first barrier metal layer is disposed on the first metal interconnector, the first metal interconnector and the first barrier metal layer have different metal materials, wherein the first barrier metal layer has a material selected from a group including Cu, Al, Ag, Au or combinations thereof.

2. The semiconductor device according to claim 1, wherein the first metal interconnector has a material of tungsten.

3. (canceled)

4. The semiconductor device according to claim 1, further comprising:
a first metal layer, disposed on the first barrier metal layer and the first dielectric layer;
a second dielectric layer, disposed on the first metal layer and the first dielectric layer; and
a second metal plug structure, embedded in the second dielectric layer and in direct contact with the first metal layer, wherein the second metal plug structure comprises at least one second metal interconnector.

5. The semiconductor device according to claim 4, wherein the second dielectric layer is further disposed on a portion of the first barrier metal layer and in direct contact with the first barrier metal layer.

6. The semiconductor device according to claim 4, wherein the second metal plug structure is in direct contact with a first surface of the first metal layer away from the first barrier metal layer and in direct contact with a portion of a second surface of the first metal layer, wherein the second surface connects to the first surface and is adjacent to the first barrier metal layer.

7. A method for manufacturing a semiconductor device, comprising:
providing a substrate, wherein a circuit element is disposed on the substrate;
forming a first dielectric layer on the substrate and on the circuit element;
forming a first through hole in the first dielectric layer, wherein the first through hole penetrates through the first dielectric layer to expose a portion of the circuit element;
forming a first metal interconnector in the first through hole to fill the first through hole, wherein the first metal interconnector is in direct contact with the circuit element;
forming a recess in a side of the first metal interconnector away from the circuit element; and
forming a first barrier metal layer in the recess, wherein the first barrier metal layer is in direct contact with the first metal interconnector, and the first metal interconnector and the first barrier metal layer have different metal materials.

8. The method for manufacturing a semiconductor device according to claim 7, wherein the first metal interconnector has a material of tungsten, and the first barrier metal layer has a material selected from a group including Cu, Al, Ti, Ta, Ag, Au and other metal elements or combinations thereof.

9. The method for manufacturing a semiconductor device according to claim 7, further comprising:
forming a first metal layer on the first barrier metal layer and the first dielectric layer;
forming a second dielectric layer on the first metal layer and the first dielectric layer;
forming a second through hole in the second dielectric layer, wherein the second through hole penetrates the second dielectric layer to expose the first metal layer; and
forming a second metal interconnector in the second through hole, wherein the second metal interconnector is in direct contact with the first metal layer.

10. The method for manufacturing a semiconductor device according to claim 9, wherein the second dielectric layer is further partially disposed on the first barrier metal layer and in direct contact with the first barrier metal layer.

11. The method for manufacturing a semiconductor device according to claim 10, wherein the second through hole is further configured to expose the second dielectric layer disposed on the first barrier metal layer.

12. The method for manufacturing a semiconductor device according to claim 9, wherein after forming the second through hole, the method further comprising performing a cleaning process on the second through hole, and then forming the second metal interconnector in the second through hole.

13. The method for manufacturing a semiconductor device according to claim 7, wherein the recess is formed by using a chemical mechanical polishing process to forming a dishing or using a etching back process to forming the recess.
